(19) United States
(12) Patent Application Publication
(10) Pub. No.: US 2026/0343091 A1
(43) Pub. Date: Oct. 29, 2026

(54) IMAGE ACQUISITION DEVICE, BOARD INSPECTION DEVICE, AND IMAGE ACQUISITION METHOD

(71) Applicant: FUJI CORPORATION, Chiryu (JP)

(72) Inventors: Hiroshi OIKE, Chiryu-shi (JP); Kenji SUGIYAMA, Anjo-shi (JP); Masafumi AMANO, Okazaki-shi (JP); Sota YOKOYAMA, Nagoya-shi (JP)

(73) Assignee: FUJI CORPORATION, Chiryu (JP)

(21) Appl. No.: 19/128,632

(22) PCT Filed: Nov. 22, 2022
(86) PCT No.: PCT/JP2022/043216

§ 371 Date: May 9, 2025

(51) Int. Cl. H04N 23/67; G06T 7/00; H04N 23/695

(52) U.S. Cl. CPC H04N 23/67; G06T 7/0004; H04N 23/695; G06T 2207/30108

(57) ABSTRACT

An image acquisition device according to the present disclosure acquires, when inspecting multiple targets disposed on a plane, images of the multiple targets, the image acquisition device including: a camera unit including a camera capable of imaging the multiple targets from above and configured to change a focus height at which the camera is in focus; and a control section configured to obtain a width in a height direction capable of being covered by a single time of imaging of the camera based on a height difference between a highest target and a lowest target among multiple targets capable of being simultaneously imaged by the camera and on a depth of field of the camera, to determine a focus height of each time of imaging, and cause the camera unit to capture each image by adjusting focus to match each determined focus height.

### TECHNICAL FIELD

The present description discloses an image acquisition device, a board inspection device, and an image acquisition method.

### BACKGROUND ART

Conventionally, an image inspection device has been known that inspects an inspection target using an image, and inspects a position or a posture of the inspection target based on images obtained by simultaneously imaging multiple inspection targets. For example, Patent Literature 1 discloses a technology of simultaneously imaging one of multiple inspection targets (hereinafter, referred to as a reference target) and an inspection target of which a distance from a surface of the reference target is shorter than a depth of field of a camera.

### CITATION LIST

### Patent Literature

Patent Literature 1: JP-A-2015-145797

### BRIEF SUMMARY

### Technical Problem

However, in the above-described image inspection device, even in a case where the distance between the multiple inspection targets other than the reference target is shorter than the depth of field of the camera, an inspection target of which the distance from the reference target is longer than the depth of field of the camera is captured separately from the reference target. For this reason, the number of times of image capturing using the camera increases, and the time required to capture the image may increase.

A main object of the present disclosure is to shorten a time required to capture an image.

The present disclosure employs the following means in order to achieve the above-described main object.

### Solution to Problem

An image acquisition device according to the present disclosure is an image acquisition device for acquiring, when inspecting multiple targets disposed on a plane, images of the multiple targets, the image acquisition device including:
a camera unit including a camera capable of imaging the multiple targets from above and configured to change a focus height at which the camera is in focus; and
a control section configured to obtain a width in a height direction capable of being covered by a single time of imaging of the camera based on a height difference between a highest target and a lowest target among multiple targets capable of being simultaneously imaged by the camera and on a depth of field of the camera, to determine a focus height of each time of imaging, and cause the camera unit to capture each image by adjusting focus to match each determined focus height.

In this image acquisition device, the width in the height direction capable of being covered by a single time of imaging of the camera is obtained based on the height difference and on the depth of field of the camera, to determine a focus height of each time of imaging, and the camera unit is caused to capture each image by adjusting focus to match each determined focus height. Accordingly, the number of times of imaging using the camera can be set to the number of times corresponding to the ratio of the height difference to the width in the height direction at most. Therefore, the time required to capture the image can be shortened.

A board inspection device according to the present disclosure is a board inspection device for inspecting a mounting state of multiple components mounted on a board, the board inspection device including:
a camera unit including a camera capable of imaging the multiple components from above and configured to change a focus height at which the camera is in focus;
a control section configured to obtain a width in a height direction capable of being covered by a single time of imaging of the camera based on a height difference between a highest target and a lowest target among multiple targets capable of being simultaneously imaged by the camera and on a depth of field of the camera, to determine a focus height of each time of imaging, and cause the camera unit to capture each image by adjusting focus to match each determined focus height; and
an inspection section configured to inspect the mounting state of the multiple components on the board based on the images.

The board inspection device has the same effect as the image acquisition device of the present disclosure.

An image acquisition method according to the present disclosure is an image acquisition method for acquiring, when inspecting multiple targets disposed on a plane, images of the multiple targets by using a camera unit including a camera capable of imaging the multiple targets from above and configured to change a focus height at which the camera is in focus, the image acquisition method including:
obtaining a height range capable of being covered by a single time of imaging of the camera based on a height difference between a highest target and a lowest target among multiple targets capable of being simultaneously imaged by the camera and on a depth of field of the camera, to determine a focus height of each time of imaging; and
causing the camera unit to capture each image by adjusting focus to match each determined focus height.

This image acquisition method has the same effects as those of the image acquisition device and the board inspection device of the present disclosure.

### BRIEF DESCRIPTION OF DRAWINGS

FIG. 1 is a schematic configuration diagram of component mounting system 1.

FIG. 2 is a schematic configuration diagram of head lifting and lowering device 50.

FIG. 3 is a block diagram illustrating an electric connection relationship in component mounting system 1.

FIG. 4 is a flowchart illustrating an example of a focus height determination processing routine.

FIG. 5 is a flowchart illustrating an example of an imaging height range setting processing subroutine.

FIG. 6A is a diagram illustrating a method of calculating height difference ΔH.

FIG. 6B is a diagram illustrating a method of calculating width h in a height direction.

FIG. 6C is a diagram illustrating a method of setting imaging height range R.

FIG. 6D is a diagram illustrating a method of determining the presence or absence of imaging and the focus height in each imaging height range R.

FIG. 7 is a diagram illustrating an example of focus data 63a.

FIG. 8 is a flowchart illustrating an example of a post-mounting component inspection processing routine.

### DESCRIPTION OF EMBODIMENTS

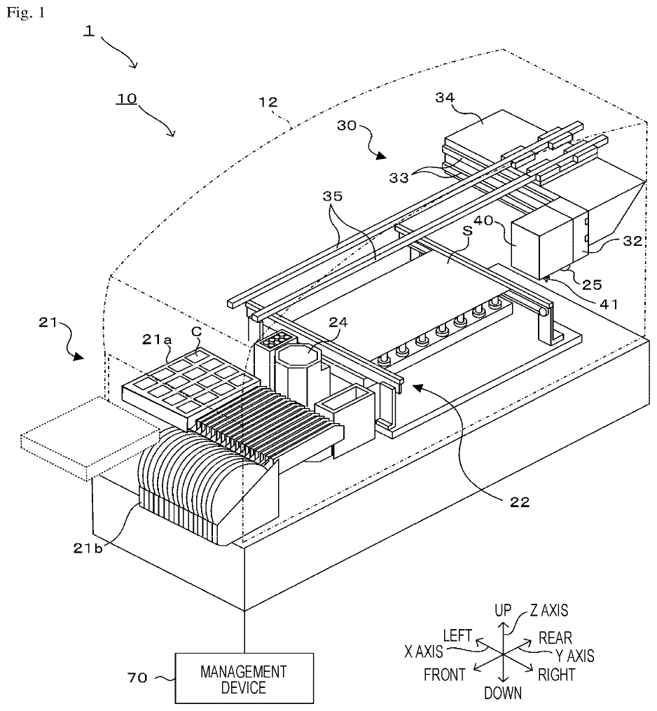

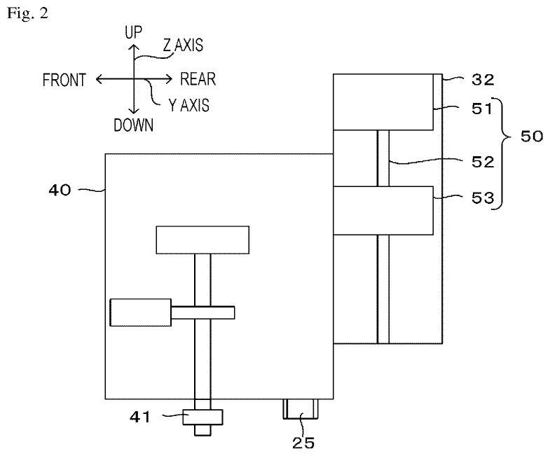

Hereinafter, an embodiment of the present disclosure will be described with reference to the drawings. FIG. 1 is a schematic configuration diagram of component mounting system 1. FIG. 2 is a schematic configuration diagram of head lifting and lowering device 50. FIG. 3 is a block diagram illustrating an electric connection relationship in component mounting system 1. In FIGS. 1 and 2, a left-right direction is an X-axis direction (a direction perpendicular to a paper surface in FIG. 2), a front-rear direction is a Y-axis direction, and an up-down direction is a Z-axis direction.

Component mounting system 1 includes component mounter 10 and management device 70 (see FIG. 3). As illustrated in FIG. 1, component mounter 10 picks up component C supplied from component supply device 21 and mounts component C on board S. As illustrated in FIG. 1, component mounter 10 includes component supply device 21, board conveyance device 22, head 40, head moving device 30, head lifting and lowering device 50 (see FIG. 2), part camera 24, mark camera 25, and control device 60 (see FIG. 3).

Component supply device 21 includes, for example, tray supply device 21a that supplies a tray having a large number of accommodation pockets accommodating components C, tape feeder 21b that feeds a tape having a large number of cavities accommodating components C, and the like.

Board conveyance device 22 conveys board S from left to right by driving a pair of conveyor belts. For example, board conveyance device 22 includes a pair of conveyor belts installed at a predetermined interval in the front-rear direction (Y-axis direction) and laid in the left-right direction (X-axis direction).

Head 40 holds suction nozzle 41 that collects (picks up) component C. Although not illustrated, a negative pressure source is connected to suction nozzle 41 via a solenoid valve (on-off valve), and suction nozzle 41 picks up component C by receiving a negative pressure supplied from the negative pressure source. Head 40 includes Z-axis actuator 42 (see FIG. 3) and Z-axis position sensor 43 (see FIG. 3). Z-axis actuator 42 (see FIG. 3) is driven to move suction nozzle 41 in the up-down direction (Z-axis direction). Z-axis position sensor 43 detects a position of suction nozzle 41 in the Z-axis direction and outputs the detected position to control device 60 (see FIG. 3).

Head moving device 30 moves head 40 in the front-rear and left-right directions (XY-axis directions). As illustrated in FIG. 1, head moving device 30 includes X-axis slider 32 and Y-axis slider 34. X-axis slider 32 is supported by pair of upper and lower X-axis guide rails 33 installed on a front surface of Y-axis slider 34 to extend in the left-right direction (X-axis direction). X-axis slider 32 is moved in the X-axis direction along X-axis guide rail 33 by driving X-axis actuator 36 (see FIG. 3). Y-axis slider 34 is supported by pair of left and right Y-axis guide rails 35 installed on an upper stage portion of housing 12 to extend in the front-rear direction (Y-axis direction). Y-axis slider 34 is moved in the Y-axis direction along Y-axis guide rail 35 by driving Y-axis actuator 38 (see FIG. 3). A position of X-axis slider 32 in the X-axis direction is detected by X-axis position sensor 37 (see FIG. 3). In addition, a position of Y-axis slider 34 in the Y-axis direction is detected by Y-axis position sensor 39 (see FIG. 3). Head 40 is attached to X-axis slider 32. Therefore, head 40 is moved along an XY plane (horizontal plane) by driving and controlling head moving device 30 (X-axis actuator 36 and Y-axis actuator 38).

Head lifting and lowering device 50 lifts and lowers head 40. As illustrated in FIG. 2, head lifting and lowering device 50 is provided on X-axis slider 32. Head lifting and lowering device 50 includes Zs-axis actuator 51, ball screw 52, movable body 53, and Zs-axis position sensor 54 (see FIG. 3). Ball screw 52 is provided to extend in the up-down direction (Z-axis direction), and is screwed into a ball nut (not illustrated) fixed to movable body 53. Therefore, movable body 53 is lifted and lowered along the up-down direction by rotationally driving ball screw 52 with Zs-axis actuator 51. Further, movable body 53 holds head 40. Accordingly, head lifting and lowering device 50 moves movable body 53 up and down by driving of Zs-axis actuator 51, to move head 40 up and down. Zs-axis position sensor 54 detects a position of head 40 in the Z-axis direction and outputs the detected position to control device 60 (see FIG. 3).

When component C supplied by component supply device 21 is collected and mounted on board S conveyed by board conveyance device 22, part camera 24 captures an image of component C from below when component C passes above part camera 24. As illustrated in FIG. 1, part camera 24 is installed between component supply device 21 and board conveyance device 22. Part camera 24 outputs the captured image to control device 60 (see FIG. 3).

Mark camera 25 images board S carried in by board conveyance device 22, component C supplied by component supply device 21, component C mounted on board S, and the like from above. As illustrated in FIG. 1, mark camera 25 is attached to head 40, and is moved in the XY-axis direction together with head 40 by head moving device 30. Mark camera 25 is moved in the Z-axis direction together with head 40 by head lifting and lowering device 50. Mark camera 25 outputs the captured image to control device 60 (see FIG. 3).

As illustrated in FIG. 3, control device 60 is configured as a microprocessor centered around CPU 61, and includes, in addition to CPU 61, ROM 62, storage (for example, HDD or SSD) 63, and RAM 64. A position signal from X-axis position sensor 37, Y-axis position sensor 39, Z-axis position sensor 43, or Zs-axis position sensor 54 is input to control device 60. In addition, an image signal from part camera 24 or mark camera 25 is also input to control device 60. Further, control device 60 calculates a pickup deviation amount of component C picked up by suction nozzle 41 using the image input from part camera 24, and inspects the mounting state of component C on board S using the image input from mark camera 25. Meanwhile, control device 60 outputs drive signals to component supply device 21, board conveyance device 22, X-axis actuator 36, Y-axis actuator 38, Z-axis actuator 42, and Zs-axis actuator 51. In addition, a control signal to part camera 24 or mark camera 25 is also output from control device 60. Storage 63 stores data used for inspecting board S.

As illustrated in FIG. 3, management device 70 is configured as a microprocessor centered around CPU 71, and includes, in addition to CPU 71, ROM 72, storage 73, and RAM 74. Management device 70 is communicably connected to control device 60. Storage 73 stores shape data for each component C to be mounted on board S, a production schedule, target mounting position data, and the like. The shape data is data storing an outer shape including a height of component C, the type of component C to be mounted on board S, and the like. The production schedule stores which components C are to be mounted in which order in component mounter 10, how many boards S (products) on which such mounting has been performed are to be manufactured, and the like. The target mounting position data stores at which position of board S each component C is mounted. The target mounting position data includes, for example, a value of an X-axis coordinate and a value of a Y-axis coordinate of each component C when a predetermined point of board S is set as an origin, an angle formed by a long side of component C and a line parallel to the Y-axis, and the like.

Next, an operation of component mounting system 1 configured as described above will be described. First, component mounting processing executed by CPU 61 of component mounter 10 will be described. CPU 61 inputs an instruction to start the production from management device 70, inputs the shape data, the production schedule, and the target mounting position data, stores the shape data, the production schedule, and the target mounting position data in storage 63, and then starts the present processing.

When this processing is started, CPU 61 causes suction nozzle 41 to pick up component C supplied from component supply device 21. Specifically, CPU 61 controls head moving device 30 (X-axis actuator 36 and Y-axis actuator 38) so that suction nozzle 41 moves to a position above the supply position of component C by component supply device 21, controls Z-axis actuator 42 so that suction nozzle 41 is lowered, and controls the solenoid valve so that the negative pressure is supplied to suction nozzle 41. Next, CPU 61 mounts component C on board S. Specifically, CPU 61 controls head moving device 30 so that component C picked up by suction nozzle 41 moves to a position above the mounting position of board S, controls Z-axis actuator 42 so that component C is pressed against board S, and controls the solenoid valve so that the pickup of component C is released. CPU 61 repeatedly executes these pieces of processing until all components C to be mounted by component mounter 10 are mounted.

Next, post-mounting component inspection processing executed by CPU 61 of control device 60 after the component mounting processing is executed will be described. When the post-mounting component inspection processing is started, CPU 61 controls head moving device 30 (X-axis actuator 36 and Y-axis actuator 38) so that mark camera 25 moves to a position above board S. Next, CPU 61 controls mark camera 25 so that the image of board S including component C is captured. Subsequently, CPU 61 sets one of mounted components C as an inspection target component. Then, CPU 61 performs image processing on the captured image, and recognizes an actual mounting position (value of X-axis coordinate, value of Y-axis coordinate, and angle) of the inspection target component on board S. Next, CPU 61 calculates a positional deviation amount based on the difference between the actual mounting position and the target mounting position. When at least one of the value of the X-axis coordinate, the value of the Y-axis coordinate, and the angle exceeds an allowable range, CPU 61 determines that the mounting state of the inspection target component is abnormal. On the other hand, when all of the value of the X-axis coordinate, the value of the Y-axis coordinate, and the angle fall within the allowable range, CPU 61 determines that the mounting state of the inspection target component is normal. Then, CPU 61 stores the determination result in storage 63. CPU 61 performs these pieces of processing on all components that are the inspection targets.

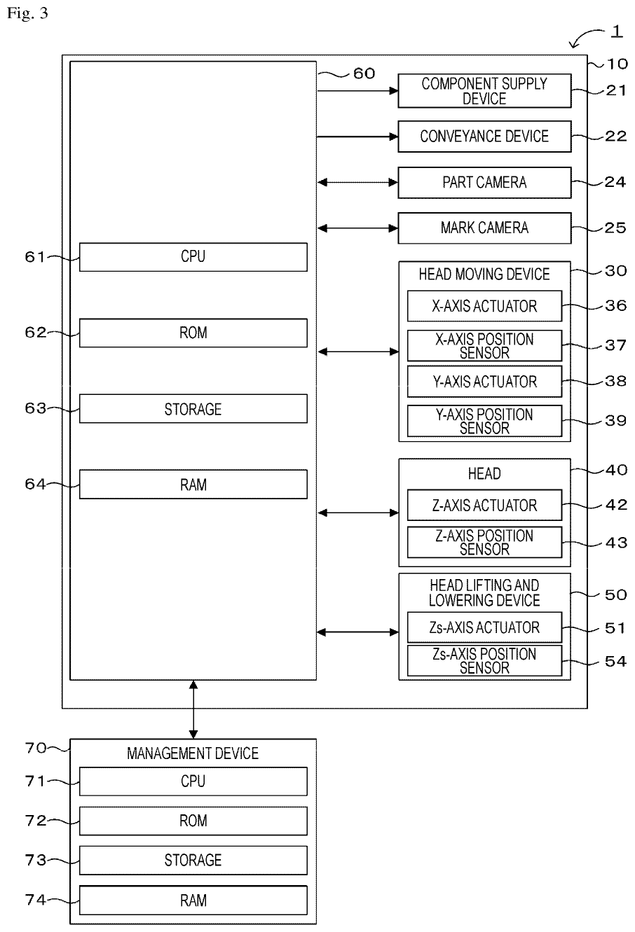

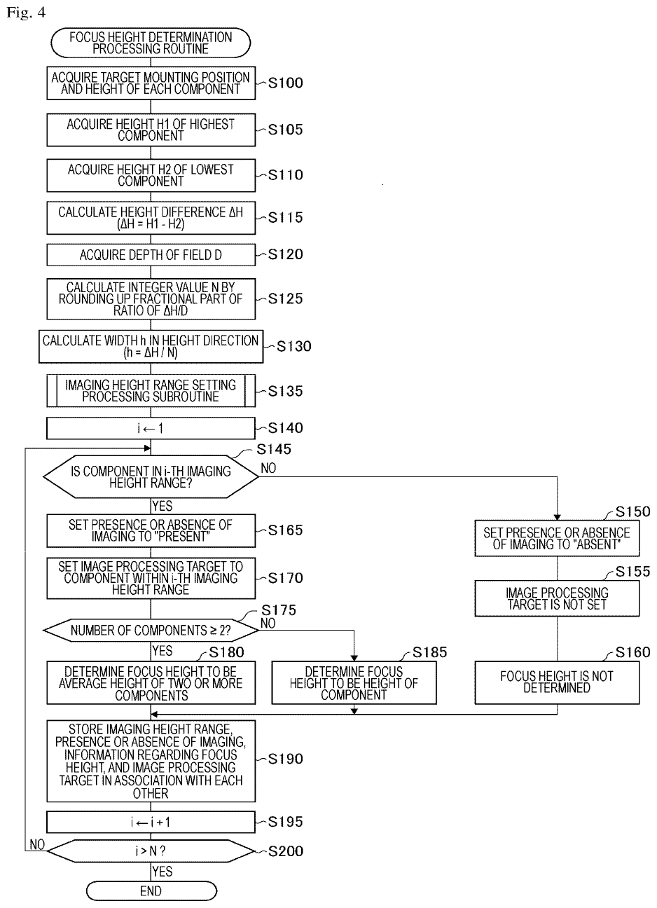

Various types of components C having different heights are mounted on board S. Therefore, when board S is imaged only once in a state where the focus of mark camera 25 is fixed at a predetermined position, there is component C imaged in a state of not being included in depth of field D of mark camera 25. There is a risk that the mounting state of component C imaged in a state of not being included in depth of field D of mark camera 25 is not correctly determined. Therefore, in the present embodiment, imaging height range R (included in depth of field D of mark camera 25) that can be covered by one imaging is determined, focus height P at which mark camera 25 is in focus is determined within imaging height range R, mark camera 25 is focused on each focus height P, board S is imaged by mark camera 25 in multiple times, and the mounting state of component C with respect to board S is inspected based on multiple images. Here, first, a focus height determination processing routine of determining focus height P will be described with reference to FIGS. 4 to 7. FIG. 4 is a flowchart illustrating an example of the focus height determination processing routine. This processing is executed by CPU 61 of control device 60 prior to the component mounting processing and the post-mounting component inspection processing described above. CPU 61 inputs a start instruction from management device 70, inputs the shape data, the production schedule, and the target mounting position data from management device 70, stores the shape data, the production schedule, and the target mounting position data in storage 63, and then executes the present routine. When board S is larger than an imaging range (horizontal direction) of mark camera 25, the division into multiple regions in the horizontal direction is performed, and then imaging is performed for inspection.

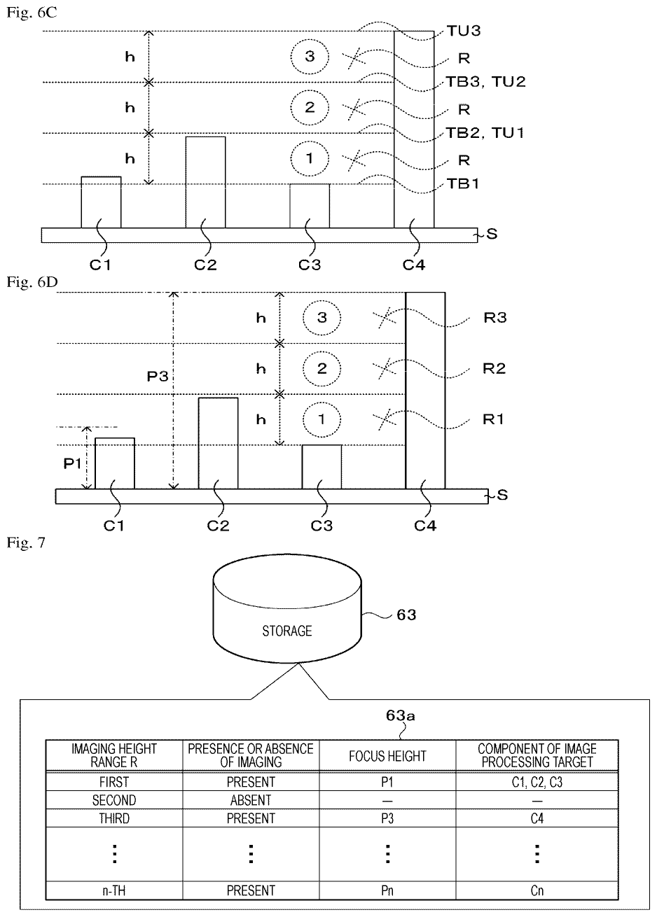

When the present routine is started, CPU 61 refers to the shape data to acquire height H of each component C, and recognizes the target mounting position of each component C with reference to the target mounting position data (S100). Next, as illustrated in FIG. 6A, CPU 61 refers to the shape data to acquire height H1 of component C having the highest height (component C4 in the example illustrated in FIG. 6A) among components C to be mounted on board S by component mounter 10 (S105). Subsequently, as illustrated in FIG. 6A, CPU 61 refers to the shape data to acquire height H2 of component C having the lowest height (component C3 in the example illustrated in FIG. 6A) among components C that are included in the imaging range in the horizontal direction of mark camera 25 and that are the inspection targets (S110). Then, as illustrated in FIG. 6A, CPU 61 subtracts height H2 from height Hl to calculate height difference ΔH (=H1−H2) between two components C (S115).

Next, CPU 61 acquires depth of field D of mark camera 25 (S120). Depth of field D of mark camera 25 is stored in storage 63 in advance. Subsequently, CPU 61 calculates a ratio (=ΔH/D) of height difference ΔH to depth of field D, calculates integer value N by rounding up the fractional part of the calculated ratio, and stores integer value N in storage 63 (S125). Then, as illustrated in FIG. 6B, CPU 61 calculates width h (=ΔH/N) of imaging height range R in the height direction by dividing height difference ΔH by integer value N (S130).

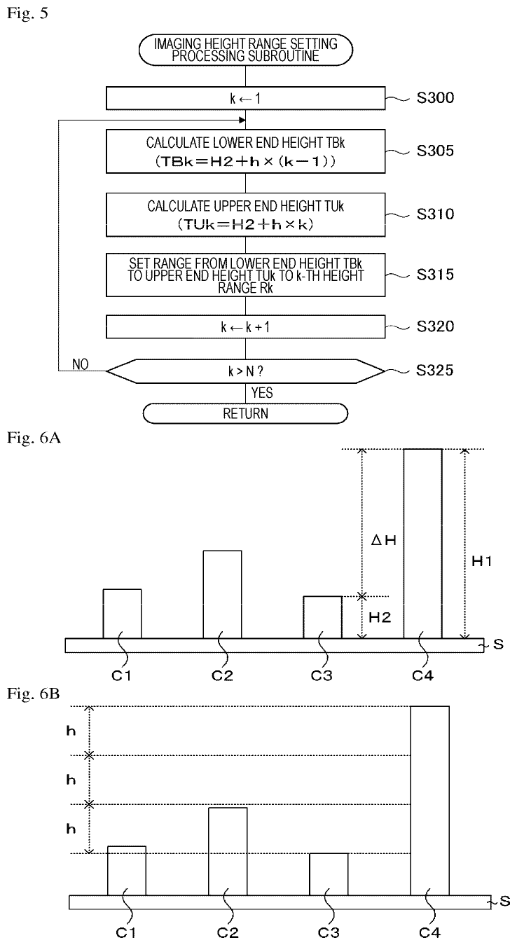

Next, CPU 61 executes an imaging height range setting processing subroutine illustrated in FIG. 5 (S135). The imaging height range setting processing subroutine is processing of setting imaging height range R.

When the imaging height range setting processing subroutine is started, CPU 61 first sets a value 1 to variable k (S300). Next, as illustrated in FIG. 6C, CPU 61 adds an integrated value of width h in the height direction and (k−1) to height H2 to calculate lower end height TBk (=H2+h×(k−1)) of k-th imaging height range R (S305). Subsequently, as illustrated in FIG. 6C, CPU 61 adds an integrated value of width h in the height direction and k to height H2 to calculate upper end height TUK (=H2+h×k) of k-th imaging height range R (S310). Then, as illustrated in FIG. 6C, CPU 61 sets a range from lower end height TBk to upper end height TUk as k-th imaging height range R (S315). In FIG. 6C, the number of circles indicated by broken lines indicates an order of imaging height range R. By repeatedly executing these pieces of processing, CPU 61 sets N (three in the example illustrated in FIG. 6C) imaging height ranges R having the same width (width h) in a region from a surface of component C having the lowest height to a surface of component C having the highest height when component C is mounted on board S.

Next, CPU 61 increments the value of variable k by 1 (S320). Then, CPU 61 determines whether the value of variable k is smaller than integer value N (S325). When the value of variable k is larger than integer value N, CPU 61 determines that N imaging height ranges R have not yet been set, and makes a negative determination. On the other hand, when the value of variable k is larger than integer value N, CPU 61 determines that N imaging height ranges R have already been set, and makes a positive determination. When a negative determination is made in S325, CPU 61 returns to S305 again. On the other hand, when a positive determination is made in S325, CPU 61 ends the imaging height range setting processing subroutine, and proceeds to S140 of the focus height determination processing routine illustrated in FIG. 4.

Subsequently, CPU 61 sets a value of variable i to 1 (S140). Then, CPU 61 compares height H of each component C acquired in S100 with lower end height TBi and upper end height TUi in i-th imaging height range R set by the imaging height range setting processing subroutine, to determine whether there is component C having height (upper surface) H within i-th imaging height range R when component C is mounted on board S (S145). CPU 61 determines that component C having lowest height H among multiple components C has height H within first imaging height range R, and determines that component C having highest height H has height H within N-th imaging height range R. When height H of component C is height H that matches a boundary between adjacent imaging height ranges R, CPU 61 determines that component C having height (upper surface) H in any one of two adjacent imaging height ranges R is included.

When there is no component C having height H within i-th imaging height range R, CPU 61 makes a negative determination. On the other hand, when there is component C having height H within i-th imaging height range R, CPU 61 makes a positive determination. When a negative determination is made in S145, CPU 61 determines to skip imaging of i-th imaging height range R in a post-mounting component inspection processing routine to be described later, and sets information regarding the presence or absence of imaging in i-th imaging height range R to “absent” (S150). Next, CPU 61 determines not to set an image processing target in the post-mounting component inspection processing routine described later (S155). Subsequently, CPU 61 determines not to determine focus height P (S160).

On the other hand, when a positive determination is made in S145, CPU 61 determines to execute imaging of i-th imaging height range R in the post-mounting component inspection processing routine to be described later, and sets the information regarding the presence or absence of imaging in i-th imaging height range R to “present” (S165). Subsequently, CPU 61 sets component C having height H within i-th imaging height range R as the image processing target (S170). Then, CPU 61 determines whether there are two or more components C having height (upper surface) H within i-th imaging height range R (S175). When it is determined that there are two or more components C having height H within i-th imaging height range R, CPU 61 makes a positive determination. On the other hand, when it is determined that there is one component C having height H within i-th imaging height range R, CPU 61 makes a negative determination. When a positive determination is made in S175, CPU 61 determines focus height P in i-th imaging height range R to be an average height of two or more components C (S180). On the other hand, when a negative determination is made in S175, CPU 61 determines focus height P in i-th imaging height range R to be height H of component C (S185).

Here, an example of the processing of S145 to S185 will be described with reference to FIG. 6D. In FIG. 6D, the number of circles indicated by broken lines indicates an order of imaging height range R. Since there are components C1, C2, and C3 as components C having height (upper surface) H within first imaging height range R, CPU 61 sets the information regarding the presence or absence of imaging in first imaging height range R to “present” (S165). Subsequently, CPU 61 sets components C1, C2, and C3 as the image processing target of the image captured in first imaging height range R (S170). Then, CPU 61 determines focus height P in first imaging height range R to be the average height (focus height P1) (S180). Further, since there is no component C having height H in second imaging height range R, CPU 61 sets the information regarding the presence or absence of imaging in second imaging height range R to “absent” (S150). Subsequently, CPU 61 determines not to set the image processing target (S155). Then, CPU 61 determines not to determine focus height P in second imaging height range R (S160). Further, since there is only component C4 as component C having height H within third imaging height range R, CPU 61 sets the information regarding the presence or absence of imaging in third imaging height range R to “present” (S165). Subsequently, CPU 61 sets component C4 as the image processing target of the image captured in third imaging height range R (S170). Then, CPU 61 determines focus height P in third imaging height range R to be the height (focus height P3) of component C4 (S185).

Next, as illustrated in FIG. 7, CPU 61 stores, in storage 63, information regarding imaging height range R (i-th), the information regarding the presence or absence of imaging, focus height P, and the image processing target in i-th imaging height range R in association with each other (S190). Then, CPU 61 increments the value of variable i by 1 (S195). Then, CPU 61 determines whether the value of variable i is larger than integer value N (S200). When the value of variable i is equal to or less than integer value N, CPU 61 determines that there is still imaging height range R in which the information regarding the presence or absence of imaging and focus height P have to be set, and makes a negative determination. On the other hand, when the value of variable i is larger than integer value N, CPU 61 determines that the information regarding the presence or absence of imaging and focus height P have been set for all imaging height ranges R, and makes a positive determination. When a negative determination is made in S200, CPU 61 returns to S145 again. On the other hand, when a positive determination is made in S200, CPU 61 ends the present routine. In the present embodiment, data obtained by repeatedly executing the processing of S145 to S175 will be referred to as focus data 63a.

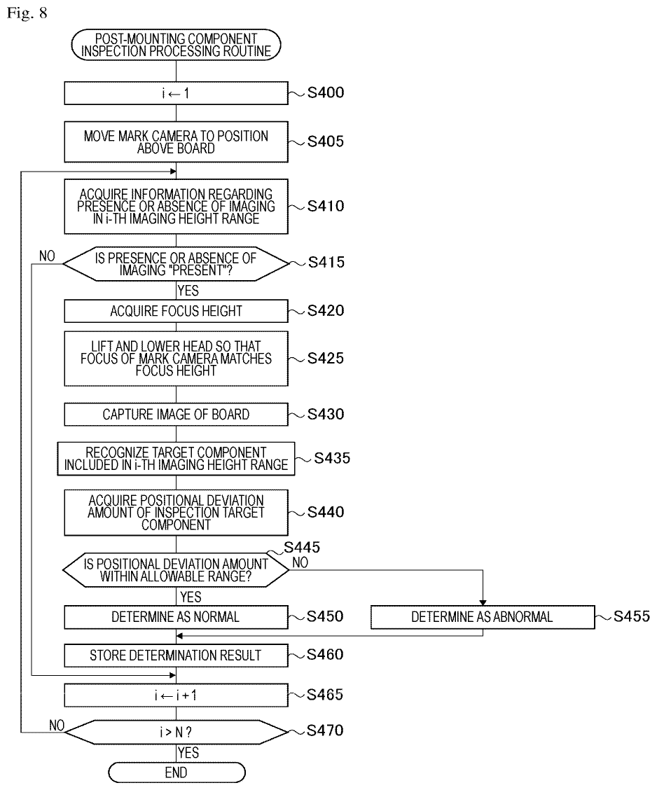

Next, the post-mounting component inspection processing executed by CPU 61 of control device 60 after component mounter 10 mounts component C on board S in the component mounting processing described above will be described. FIG. 8 is a flowchart illustrating an example of the post-mounting component inspection processing routine.

When the present routine is started, CPU 61 sets the value of variable i to 1 (S400). Next, CPU 61 controls head moving device 30 so that mark camera 25 moves to a position above board S (S405). Subsequently, CPU 61 refers to focus data 63a illustrated in FIG. 7 to acquire the information regarding the presence or absence of imaging in i-th imaging height range R (S410). Then, CPU 61 determines whether the information regarding the presence or absence of imaging acquired in S410 is “present” (S415). When the information regarding the presence or absence of imaging acquired in S 410 is “absent”, CPU 61 determines to skip imaging in i-th imaging height range R and makes a negative determination. On the other hand, when the information regarding the presence or absence of imaging acquired in S410 is “present”, CPU 61 determines to execute imaging in i-th imaging height range R and makes a positive determination. When a negative determination is performed in S415, CPU 61 proceeds to S465. On the other hand, when a positive determination is made in S415, CPU 61 refers to focus data 63a illustrated in FIG. 7 to acquire focus height P in i-th imaging height range R (S420). Then, CPU 61 sets a target height of head 40 such that the focus height of mark camera 25 matches focus height P acquired in S420, and controls head lifting and lowering device 50 (Zs-axis actuator 51) so that head 40 moves to the target height (S425).

Next, CPU 61 controls mark camera 25 so that the image of board S is captured (S430). Subsequently, CPU 61 refers to focus data 63a illustrated in FIG. 7 to recognize component C that is the image processing target of the image captured in i-th imaging height range R (S435). Then, CPU 61 processes the image captured in S430 to calculate the positional deviation amount of component C (S440).

Next, CPU 61 determines whether the positional deviation amount of component C acquired in S440 is within the allowable range (S445). When a positive determination is made in S445, it is determined that the mounting state is normal (S450). On the other hand, when a negative determination is made in S445, it is determined that the mounting state is abnormal (S455). In the present embodiment, the processing in steps S435 to S455 will be referred to as inspection processing. The specific contents of the inspection processing have been described above. After S450 or after S455, CPU 61 stores the determination result in storage 63 (S460).

Next, CPU 61 increments a value of variable i by 1 (S465). Then, CPU 61 determines whether the value of variable i is larger than integer value N (S470). The integer value N is stored in storage 63 in S125 of the focus height determination processing routine. When the value of variable i is equal to or less than integer value N, CPU 61 determines that there is imaging height range R for which the information regarding the presence or absence of imaging has not yet been acquired and there is component C that is not a target of inspection processing, and makes a negative determination. On the other hand, when the value of variable i is larger than integer value N, CPU 61 determines that it has acquired the information regarding the presence or absence of imaging in all imaging height ranges R and that the inspection processing has been executed on all components C, and makes a positive determination. When a negative determination is made in S470, CPU 61 returns to S410 again. On the other hand, when a positive determination is made in S470, CPU 61 ends the present routine.

In component mounter 10, the focus height is adjusted for each imaging height range R divided in accordance with depth of field D of mark camera 25 with respect to the height range from lowest component C to highest component C, and the imaging is performed. When it is determined in S145 of the focus height determination processing routine that there is no component C having height H within imaging height range R, CPU 61 sets the presence or absence of imaging in imaging height range R to “absent”. Then, in the post-mounting component inspection processing routine, when the information regarding the presence or absence of imaging is “absent”, CPU 61 skips the processing of S420 to S460 (imaging of board S). Therefore, the number of times of imaging using mark camera 25 can be reduced, and the time required to capture the image can be shortened.

Here, a correspondence relationship between the elements of the present embodiment and the elements of the present disclosure will be clarified. That is, component mounter 10 of the present embodiment corresponds to an image acquisition device of the present disclosure, mark camera 25 and head lifting and lowering device 50 correspond to a camera unit of the image acquisition device, and CPU 61 that executes the processing of S105 to S180 of the focus height determination processing routine corresponds to a control section of the image acquisition device. In addition, component mounter 10 corresponds to a board inspection device of the present disclosure, mark camera 25 and head lifting and lowering device 50 correspond to a camera unit of the board inspection device, CPU 61 that executes the processing of S105 to S165 of the focus height determination processing routine corresponds to a control section of the board inspection device, and CPU 61 that executes the post-mounting component inspection processing routine corresponds to an inspection section.

In component mounter 10 described in detail above, the width in the height direction that can be covered by a single time of imaging of the camera is obtained, the focus height of each time of imaging is determined, and the camera unit is caused to capture each image by adjusting focus to match each determined focus height. Based on height difference ΔH and depth of field D of mark camera 25, width h in the height direction that can be covered by a single time of imaging of mark camera 25 is obtained, the focus height of each time of imaging is determined, and mark camera 25 and head lifting and lowering device 50 are caused to capture each image by adjusting focus to match each determined focus height. Accordingly, the number of times of imaging using mark camera 25 can be set to the number of times corresponding to the ratio of height difference ΔH to width h in the height direction at most. Therefore, the number of times of imaging using mark camera 25 can be reduced, and the time for imaging using mark camera 25 can be shortened.

In component mounter 10, integer value N of the ratio of height difference ΔH to depth of field D of mark camera 25 is calculated, and height difference ΔH is equally divided by integer value N to obtain width h in the height direction. Accordingly, width h in the height direction can be set to an appropriate length.

Further, in component mounter 10, each imaging height range R covered by each time of imaging is set between highest component C and lowest component C based on width h in the height direction, and each focus height P is determined within each imaging height range R. As a result, it is possible to set the number of times of imaging that is just enough to image all components C based on width h in the height direction.

In addition, in component mounter 10, in a case where none of components C is included in any of imaging height ranges R, image capturing within corresponding imaging height range R is skipped. Accordingly, the number of times of imaging using mark camera 25 can be further reduced.

When multiple components C are included in any one of imaging height ranges R, component mounter 10 determines the focus height in corresponding imaging height range R to be the average height of multiple components C included in corresponding imaging height range R. Accordingly, multiple components C can be imaged at a position closer to the focus position of the lens in mark camera 25.

It goes without saying that the present disclosure is not limited to the above-described embodiment in any way, and hence can be practiced in various aspects as long as the aspects fall within the technical scope of the present disclosure.

In the above-described embodiment, the focus height determination processing routine is executed by CPU 61 of control device 60. However, the focus height determination processing routine may be executed by CPU 71 of management device 70.

In the above-described embodiment, focus height P in imaging height range R is determined based on the number of components C included in imaging height range R. However, focus height P in imaging height range R may be a constant position determined for each imaging height range R regardless of the number of components C having height (upper surface) H within imaging height range R. In this case, focus height P may be a center height in the height direction in each imaging height range R.

In the above-described embodiment, lower end height TBk of k-th imaging height range R is calculated by adding the integrated value of width h in the height direction and (k−1) to height H2, and upper end height TUk of k-th imaging height range R is calculated by adding the integrated value of width h in the height direction and k to height H2. However, lower end height TBk of k-th imaging height range R may be calculated by subtracting the integrated value of width h in the height direction and k from height H1, and upper end height TUK of k-th imaging height range R may be calculated by subtracting the integrated value of width h in the height direction and (k−1) from height H1.

In the above-described embodiment, the post-mounting component inspection processing is executed by component mounter 10. However, the post-mounting component inspection processing may be executed by using a dedicated inspection device (for example, an appearance inspection device).

In the above-described embodiment, the post-mounting component inspection may be performed on component C mounted by component mounter 10. Alternatively, in a component mounting line including multiple component mounters 10, the post-mounting component inspection may be performed on component C mounted by component mounter 10 disposed upstream of component mounter 10. In this case, in the component mounting line, the post-mounting component inspection may be performed by component mounter 10 disposed on the most downstream side.

In the above-described embodiment, the present disclosure has been described as component mounter 10, but may be an image acquisition method.

### INDUSTRIAL APPLICABILITY

The present disclosure can be applied to the manufacturing industry of a component mounter, a component mounting system, and the like.

### REFERENCE SIGNS LIST

1: component mounting system, 10: component mounter, 12: housing, 21: component supply device, 21a: tray supply device, 21b: tape feeder, 22: board conveyance device, 24: part camera, 25: mark camera, 30: head moving device, 32: X-axis slider, 33: X-axis guide rail, 34: Y-axis slider, 35: Y-axis guide rail, 36: X-axis actuator, 37: X-axis position sensor, 38: Y-axis actuator, 39: Y-axis position sensor, 40: head, 41: suction nozzle, 42: Z-axis actuator, 43: Z-axis position sensor, 50: head lifting and lowering device, 51: Zs-axis actuator, 52: ball screw, 53: movable body, 54: Zs-axis position sensor, 60: control device, 61: CPU, 62: ROM, 63: storage, 63a: focus data, 64: RAM, 70: management device, 71: CPU, 72: ROM, 73: storage, 74: RAM, C, C1 to C4: component, D: depth of field, H1: height, H2: height, N: integer value, P, P1, P3: focus height, R: imaging height range, S: board, ΔH: height difference.

1. An image acquisition device for acquiring, when inspecting multiple targets disposed on a plane, images of the multiple targets, the image acquisition device comprising:
a camera unit including a camera capable of imaging the multiple targets from above and configured to change a focus height at which the camera is in focus; and
a control section configured to obtain a width in a height direction capable of being covered by a single time of imaging of the camera based on a height difference between a highest target and a lowest target among multiple targets capable of being simultaneously imaged by the camera and on a depth of field of the camera, to determine a focus height of each time of imaging, and cause the camera unit to capture each image by adjusting focus to match each determined focus height.

2. The image acquisition device according to claim 1, wherein the control section is configured to calculate an integer value of a ratio of the height difference to the depth of field and equally divide the height difference by the integer value to obtain the width in the height direction.

3. The image acquisition device according to claim 1, wherein the control section is configured to set each imaging height range covered by each time of imaging between the highest target and the lowest target based on the width in the height direction, and determine each focus height within each imaging height range.

4. The image acquisition device according to claim 3, wherein the control section is configured to, in a case where none of the targets is included in any one of the imaging height ranges, skip image capturing within a corresponding imaging height range.

5. The image acquisition device according to claim 3, wherein the control section is configured to, in a case where the multiple targets are included in any one of the imaging height ranges, determine a focus height in a corresponding imaging height range to be an average height of the multiple targets included in the corresponding imaging height range.

6. The image acquisition device according to claim 1,
wherein the camera unit includes a lifting and lowering section configured to change the focus height by lifting and lowering the camera, and
the control section is configured to control the lifting and lowering section so that the camera moves to a lifting and lowering position corresponding to the determined focus height.

7. A board inspection device for inspecting a mounting state of multiple components mounted on a board, the board inspection device comprising:
a camera unit including a camera capable of imaging the multiple components from above and configured to change a focus height at which the camera is in focus;
a control section configured to obtain a width in a height direction capable of being covered by a single time of imaging of the camera based on a height difference between a highest target and a lowest target among multiple targets capable of being simultaneously imaged by the camera and on a depth of field of the camera, to determine a focus height of each time of imaging, and cause the camera unit to capture each image by adjusting focus to match each determined focus height; and
an inspection section configured to inspect the mounting state of the multiple components on the board based on the images.

8. An image acquisition method for acquiring, when inspecting multiple targets disposed on a plane, images of the multiple targets by using a camera unit including a camera capable of imaging the multiple targets from above and configured to change a focus height at which the camera is in focus, the image acquisition method comprising:
obtaining a height range capable of being covered by a single time of imaging of the camera based on a height difference between a highest target and a lowest target among multiple targets capable of being simultaneously imaged by the camera and on a depth of field of the camera, to determine a focus height of each time of imaging; and
causing the camera unit to capture each image by adjusting focus to match each determined focus height.
